(19) United States
(12) Patent Application Publication
(10) Pub. No.: US 2011/0016367 A1
(43) Pub. Date: Jan. 20, 2011

(54) SKEW TOLERANT SCANNABLE MASTER/SLAVE FLIP-FLOP INCLUDING EMBEDDED LOGIC

(76) Inventors: Bo Tang, Cupertino, CA (US); Edgardo F. Klass, Cupertino, CA (US)

Correspondence Address: Meyertons, Hood, Kivlin, Kowert & Goetzel, P.C., The Chase Building, 700 Lavaca, Suite 800, Austin, TX, 78701-3102, US

(21) Appl. No.: 12/502,366

(22) Filed: Jul. 14, 2009

(51) Int. Cl. G01R 31/3177; G06F 11/25

(52) U.S. Cl. 714/731; 714/E11.155

(57) ABSTRACT

An integrated circuit includes a flip-flop circuit having a master latch unit and a slave latch unit. The master latch unit includes a data latch that may receive a data value on a data input, and a scan latch that may receive a scan data value on a scan data input. The data latch may latch and output the data value on an output line in response to a transition of a first clock signal, while the scan latch may latch and output the scan data value on the output line in response to a transition of a second clock signal. The slave latch unit may latch and output either the data value or the scan data value. The flip-flop circuit also includes a clock select circuit that may selectively provide either the first clock signal or the second clock signal dependent upon a scan enable signal.

### BACKGROUND OF THE INVENTION

1. Field of the Invention

This invention relates to integrated circuits and, more particularly, to master/slave flip-flop circuits.

2. Description of the Related Art

During the design cycle of many integrated circuits, testability features may be inserted into the design to make the circuit more testable during production testing. One testing methodology, referred to as scan testing, allows data that has propagated through the device logic to be captured by sequential logic elements such as flip-flops using the clock signal of the circuit. The captured data values may then be scanned out of the device using a scan chain in which a number of such flip-flops are serially linked together. Scan testing is widely accepted due to its high test coverage percentages and the capability of automated scan logic insertion and test pattern generation tools.

Although scan testing has many advantages, there may be some drawbacks in some timing sensitive circuits. One such drawback may be datapath delay on some scannable circuit elements. For example, in a conventional scannable D flip-flop, a two-input multiplexer is inserted at the D input of the flip-flop. The two inputs are typically a data input and scan data input. This type of flip-flop is commonly referred to as a mux-D flip-flop. The multiplexer allows the data from the circuit datapath to be captured through the data input during a normal clock cycle, and scanned out during a scan test. The multiplexer may be switched via a scan enable signal to select the scan data input which may be a data value from a previous flip-flop in the scan chain. Although circuit designers try to keep the datapath delay associated with multiplexer small, in some cases, it may be unacceptable.

### SUMMARY

Various embodiments of a skew tolerant scannable flip-flop circuit are disclosed. In one embodiment, an integrated circuit may include a flip-flop circuit including a master latch unit coupled to a slave latch unit. The master latch unit includes a data latch that may be configured to receive a data value on a data input. The master latch unit may also include a scan latch that may be configured to receive a scan data value on a scan data input. The data latch may be configured to latch and output the data value on an output line in response to a transition of a first clock signal, while the scan latch may be configured to latch and output the scan data value on the output line in response to a transition of a second clock signal. The slave latch unit may be coupled to the output line and configured to latch and output either the data value or the scan data value in response to a transition of a third clock signal. The flip-flop circuit also includes a clock select circuit that may be configured to selectively provide either the first clock signal or the second clock signal dependent upon a scan enable signal.

In some embodiments, the clock select circuit may also delay a system clock by some predetermined delay to generate the first and second clock signals. This delay may enable the data latch to capture data values that arrive late, and may thus provide clock skew tolerance in some circuits.

### BRIEF DESCRIPTION OF THE DRAWINGS

FIG. 1 is a block diagram of an integrated circuit including one embodiment of skew tolerant scannable master-slave flip-flops.

FIG. 2 is a block diagram of one embodiment of a scannable master/slave flip-flop of FIG. 1.

FIG. 3 is a schematic representation of one embodiment of the master latch depicted in FIG. 2.

FIG. 4 is a circuit schematic representation of another embodiment of the master latch depicted in FIG. 2.

FIG. 5 is a block diagram of a system including an embodiment of the integrated circuit shown in FIG. 1.

While the invention is susceptible to various modifications and alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the spirit and scope of the present invention as defined by the appended claims. The headings used herein are for organizational purposes only and are not meant to be used to limit the scope of the description. As used throughout this application, the word “may” is used in a permissive sense (i.e., meaning having the potential to), rather than the mandatory sense (i.e., meaning must). Similarly, the words “include,” “including,” and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six interpretation for that unit/circuit/component.

### DETAILED DESCRIPTION

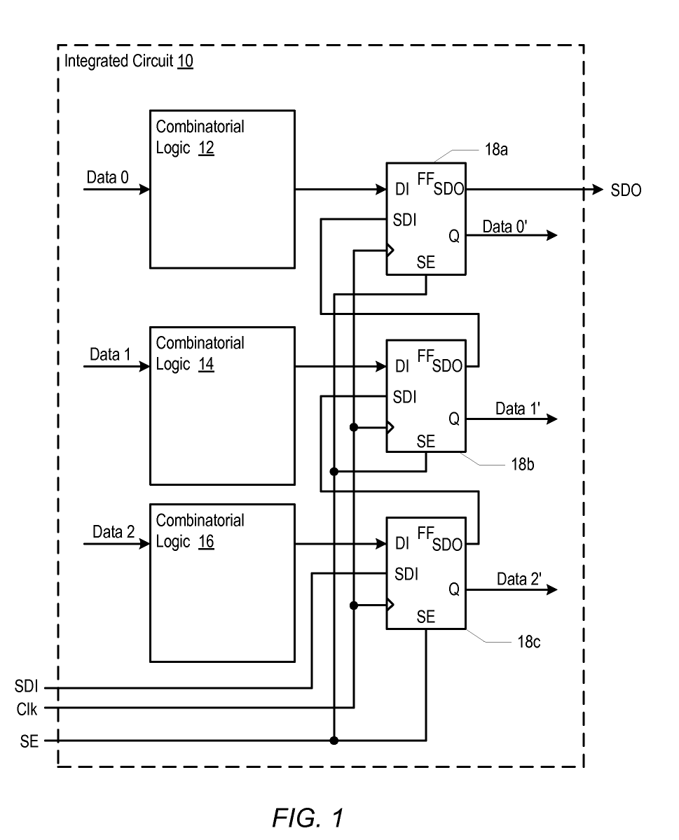

Turning now to FIG. 1, a block diagram of an integrated circuit including one embodiment of skew tolerant scannable master-slave flip-flops is shown. As described above, combinatorial logic may propagate signals to a sequential circuit element such as a flip-flop, for example. Accordingly, the integrated circuit 10 includes three exemplary combinatorial logic blocks, designated 12, 14, and 16. Combinatorial logic block 12 is coupled to receive and propagate data 0 to flip flop 18a. Similarly, combinatorial logic block 14 is coupled to receive and propagate data 1 to flip flop 18b, and likewise for combinatorial logic block 16 and flip-flop 18c. Each flip-flop is coupled to receive a clock signal (Clk), and a scan enable signal (SE). In addition, flip-flop 18c is coupled to receive a scan data in signal (SDI), while flip-flop 18a is coupled to provide a scan data out signal (SDO). As shown, the each flip-flop is coupled to provide a data out signal. In addition, the three flip-flops are coupled together serially via their respective SDO and SDI pins. It is noted that components having reference designators with a number and a letter may be referred to by the number only where appropriate.

It is noted that combinatorial logic blocks 12, 14 and 16 may be representative of any type of combinatorial logic that may be found on an integrated circuit. For example, the logic may be part of a sea of gates block, or some specialized logic block. As such, the combinatorial logic blocks may be any circuit that provides a data signal.

As described above, flip-flops 18a-18c are scannable flip-flops. As described in greater detail below, flip-flops 18a-18c may be implemented as skew tolerant scannable master/slave flip-flops with an improved datapath delay. In addition, each of flip-flops 18a-18c may include embedded logic that may be used by logic synthesis tools during circuit design.

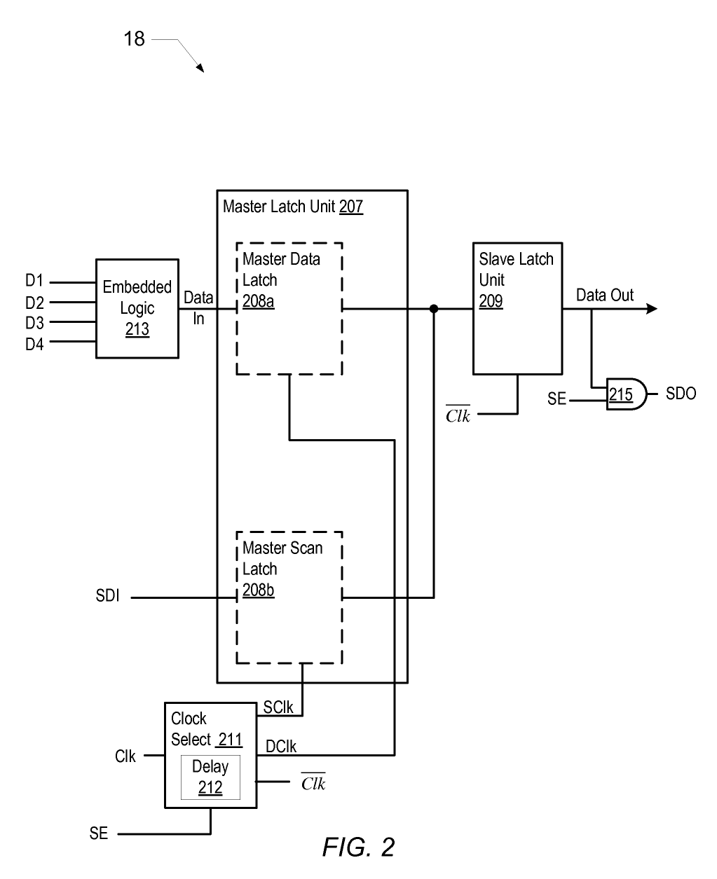

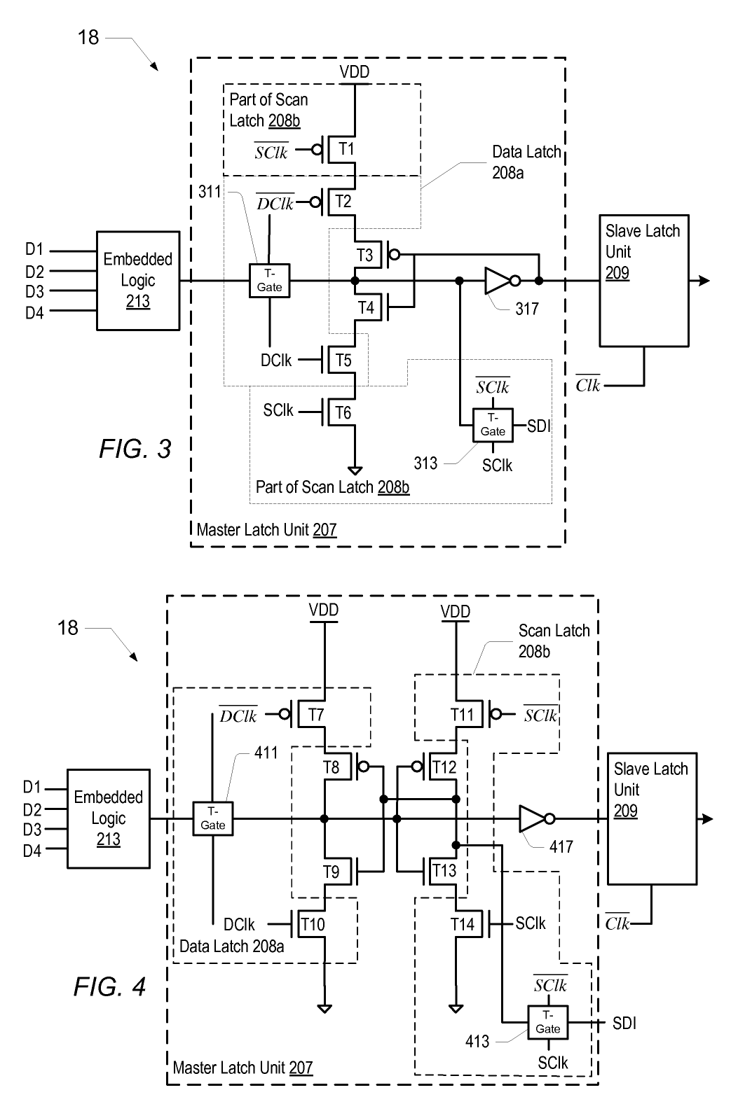

Referring to FIG. 2, a conceptual block diagram of one embodiment of a scannable master/slave flip-flop 18 is shown. Flip-flop 18 includes a master latch unit 207 coupled to a slave latch unit 209. The master latch unit 207 is coupled to receive a data in signal (e.g., Data In) from an embedded logic block 213, which is in turn coupled to receive four data signals (e.g., D1, D2, D3, and D4). The slave latch unit 209 is coupled to an AND gate 215 and also to provide a Data Out signal. The AND gate 215 is coupled to the SE signal, and provides a corresponding SDO signal (when SE is active). As shown, the master latch unit 207 includes a master data latch 208a and a master scan latch 208b. The master data latch 298a is coupled to the slave latch 209, and master scan latch 208b is also coupled to the slave latch unit 209. A clock select unit 211 is coupled to receive the SE signal and a Clk signal, and is configured to provide a data clock (DClk) to the master data latch 208a, a scan clock (SClk) to the master scan latch 208b (when the SE is active), and a C̅l̅k̅ signal to the slave latch unit 209. In addition as described further below and shown in FIG. 3 and FIG. 4, clock select unit 211 may also provide the inverted clock signals, D̅C̅l̅k̅ and S̅C̅l̅k̅. It is noted that specific logic gates (e.g., AND 215) are shown for discussion purposes only, and it is contemplated that in other embodiments other logic gates (e.g., NAND, NOR etc.) and/or functions may be used as desired.

As described above, a conventional scannable flip-flop typically includes a two-input multiplexer at the D input of the flip-flop. The multiplexer may be implemented as a complex complementary metal oxide semiconductor (CMOS) gate that may include a number of transistors coupled in such as way as to form a 2-1 multiplexer having the scan enable signal as the mux select. When a datapath is identified as a critical path, the flip-flop 18 may be used in place of a conventional scannable flip-flop. More particularly, flip-flop 18 does not use an internal multiplexer to select between the scan data and the normal data, and as such the normal data path delay may be less for flip-flop 18 than the path delay of a conventional scannable flip-flop that uses a scan mux implementation. Accordingly, during the design process the logic designer may choose a custom cell that implements flip-flop 18 from the library, instead of a cell that implements a flip-flop with scan mux at its input.

For designs that use flip-flop 18, the transistors that would have been used to form the scan mux may still be placed and used. In one embodiment, those transistors may be implemented as logic embedded in the flip-flop 18 that the synthesis tool may use. For example, if there is logic in the normal datapath just before the flip-flop 18, then that logic may be implemented using the transistors that would have been in the scan mux. Accordingly, in one embodiment, the embedded logic block 213 may be implemented as any of a variety of logic gates. For example, in one embodiment, a four-input AND/OR/Invert (AOI) logic block may be implemented by a synthesis tool if the tool needs the gates in the combinatorial device logic. If all or part of the logic isn't needed, the synthesis tool may tie off any unused inputs to an appropriate logic level. Thus, as described above, in various embodiments any number of custom cells may be created to implement flip-flop 18, each having an embedded logic block 213 that is implemented as a different combinatorial logic function.

Conceptually, during normal circuit operation of flip-flop 18, data coming from another part of integrated circuit 10 (e.g., combinatorial logic 12) may pass through embedded logic 213. The SE signal is deasserted or is inactive (e.g., logic level zero). Thus the clock select circuit 211 is providing the DClk signal, which is clocking the master data latch 208a. In one embodiment, during the time DClk is low, the master data latch 208a is transparent and the Data In signal passes through to the slave. Because the SE signal is inactive, the master scan latch 208b is not clocked and is thus not providing a master scan latch output. At the rising edge of DClk, the master data latch 208a latches the Data In signal. At about the same time, the slave latch unit 209 is transparent, and on the rising edge of C̅l̅k̅ (which may be an inverted version of DClk), the slave latch unit 209 latches and outputs the Data Out signal.

During scan mode, the SE is “asserted” or becomes active (e.g., logic level one) such as during a scan test, for example. Accordingly, the clock select circuit 211 provides the SClk signal instead of the DClk signal (which becomes inactive) and in one embodiment may be held to a given logic level. Thus, with DClk held inactive, master data latch 208a is not clocked and is thus not passing the master data latch output. During the time that SClk is low, the scan latch 208b is transparent, replacing the previously latched data value and passing the scan data value provided on the SDI pin to the slave latch unit 209. At the rising edge of SClk, the scan latch 208b latches the SDI signal. At about the same time, the slave latch unit 209 is transparent, and on the rising edge of C̅l̅k̅ (which may be an inverted version of SClk), the slave latch unit 209 latches and outputs the scan data on the Data out path and through the AND gate 215 to the SDO output. Accordingly, the scan data path is in parallel with, and separate from, the data path.

In one embodiment, the clock select circuit 211 may be implemented using combinatorial logic including strings of inverters and other logic gates such as NOR gates, for example. As such, the DClk and SClk signals (and their complements) may be delayed relative to the system clock (Clk) that may be used to drive the combinatorial system logic in the datapath. This added delay 212 may serve to provide skew tolerance in the datapath since a later-arriving data signal may still be captured by the master latch unit 207. Thus the skew may be absorbed in those cases in which the datapath has such a skew. In one embodiment, the added delay may be a predetermined amount that may be ideally substantially equivalent to any clock skew between the clock used to drive the data on the datapath and the clock used to clock the flip-flop 18. It is noted that in various embodiments, a variety of logic gate types may be used to implement the clock select circuit 211.

It is noted that the above embodiment describes positive edge triggered operation. However, in other embodiments, negative edge triggered operation may be implemented. In addition, the above description of FIG. 2 is a high-level description based on the conceptual illustration shown in FIG. 2. However, the illustrations of FIG. 3 and FIG. 4, are more detailed, and as such more detailed descriptions will be used for at least portions of the flip-flop 18.

Turning to FIG. 3, a schematic representation of portions of one embodiment of the flip-flop 18 depicted in FIG. 2 is shown. It is noted that components that correspond to those shown in FIG. 2 are numbered identically for clarity and simplicity. Similar to the flip-flop 18 of FIG. 2, the flip-flop 18 of FIG. 3 includes embedded logic 213 which is coupled to receive four data paths labeled D1-D4. As shown, the embedded logic 213 is coupled to a master latch unit 207, which is in turn coupled to a slave latch unit 209. However, the master latch unit 207 of FIG. 3 includes implementation details of data latch 208a and scan latch 208b. For example, in the illustrated embodiment, master latch unit 207 includes a T-gate 311 coupled to a transistor stack that includes six transistors T1-T6. As shown the transistors are serially coupled between VDD and circuit ground. That is to say the transistors are coupled source to drain (or drain to source) from VDD to ground. A node in the middle of the transistor stack is coupled to slave latch unit 209.

In the illustrated embodiment, the transistor stack includes three PMOS transistors (e.g., T1-T3) and three NMOS transistors (e.g., T4-T6). As shown, transistors T1 and T6, along with T-gate 313 are part of the scan latch 208b. Similarly, transistors T2 and T5, along with T-gate 311 are part of data latch 208a. Transistors T3 and T4 and inverter 317 are shared by both latches.

In one embodiment, the T-gate 311 is coupled to receive clock signals D̅C̅l̅k̅ and DClk. In various embodiments, T-gates may include parallel coupled NMOS and PMOS transistors, and the two complementary clock signals may be used to turn on (i.e., close the switch) the T-gate, thereby allowing the T-gate to pass the desired signal. Thus, in one embodiment, when DClk is low and D̅C̅l̅k̅ is high, the T-gate 311 is passing the data on the datapath. Similarly, T-gate 313 passes scan data during operation of the scan clock signals SClk and S̅C̅l̅k̅.

During normal operation (i.e., not scan mode) in a given clock cycle, when DClk is low and D̅C̅l̅k̅ is high, the T-gate 311 passes the data signal to the node between transistors T3 and T4. If the data has a logic value of one, the inverter 317 causes a logic value of zero to appear at the gates of transistors T3 and T4, causing T3 to conduct and T4 to turn off. In addition, in one embodiment, since SE is inactive, SClk is held high and S̅C̅l̅k̅ is held low, thereby causing transistors T1 and T6 to conduct. Conversely, upon the rising edge of DClk and the falling edge of D̅C̅l̅k̅, T-gate 311 stops conducting and transistors T2 and T5 begin conducting. Since transistor T3 is conducting, a path from VDD to the node between transistors T3 and T4 is created, thereby reinforcing and latching the logic value of one at the node. Thus the data value is now captured in the data latch 208a. Had the data been a logic value of zero, transistor T4 would have been conducting instead of T3, thereby reinforcing and latching a logic value of zero at the node. As mentioned above, the captured value is now available at the slave latch unit 209, which captures the data value upon a rising edge of C̅l̅k̅. The above operation may occur for each successive clock cycle of DClk.

In one embodiment, during scan mode the SE signal becomes active (e.g., a logic value of one). Accordingly, as described above, the DClk and D̅C̅l̅k̅ signals may be held inactive (e.g., logic values of one and zero respectively), and the SClk and S̅C̅l̅k̅ signals become active. Thus, the T-gate 313 begins conducting when SClk is low and S̅C̅l̅k̅ is high. This allows the SDI signal to pass through the T-gate 313 to the node between transistors T3 and T4, thus overwriting the data value that was present at the node. As above, if the SDI value is a logic value of one, the inverter 317 causes a logic value of zero to appear at the gates of transistors T3 and T4, causing T3 to conduct and T4 to turn off. Since DClk is held high and D̅C̅l̅k̅ is held low, transistors T2 and T5 are conducting. Upon the rising edge of SClk and the falling edge of S̅C̅l̅k̅, T-gate 313 stops conducting and transistors T1 and T6 begin conducting. Since transistor T3 is conducting, a path from VDD to the node between transistors T3 and T4 is created, thereby reinforcing and latching the logic value of one at the node. Thus the scan data value is now captured in the scan data latch 208b. Had the data been a logic value of zero, transistor T4 would have been conducting, thereby reinforcing and latching a logic value of zero at the node. As mentioned above, the captured value is now available at the slave latch unit 209, which captures the scan data value upon a rising edge of C̅l̅k̅.

During scan mode several clock cycles worth of scan data may be scanned through the scan chain. Accordingly, the SE signal may stay active long enough to clock all the scan data through the scan chain. For example, if there are 100 flip-flops in the scan chain, then the SE signal may stay active for 100 clock cycles. To resume normal operation the SE signal may be deasserted, and the data that is present at the Data In pin of the flip-flop 207 may be captured.

It is noted that for simplicity various circuit components may have been omitted. For example, in one embodiment, there may be a number of inverters and/or buffers in the SDI datapath within the master latch unit 207 and the slave latch unit 209 that are not shown.

Referring to FIG. 4, a schematic representation of portions of another embodiment of the flip-flop 18 depicted in FIG. 2 is shown. It is noted that components that correspond to those shown in FIG. 2 and FIG. 3 are numbered identically for clarity and simplicity. Similar to the flip-flop 18 of FIG. 2 and FIG. 3, the flip-flop 18 of FIG. 4 includes embedded logic 213 which is coupled to receive four data paths labeled D1-D4. As shown, the embedded logic 213 is coupled to a master latch unit 207, which is in turn coupled to a slave latch unit 209. However, the master latch unit 207 of FIG. 4 includes implementation details of data latch 208a and scan latch 208b that are different than the embodiment shown in FIG. 3. Accordingly, the although implementations are different, the operation of the embodiment shown in FIG. 4 is similar to the operation of the embodiment shown in FIG. 3 and described further below.

More particularly, in the embodiment illustrated in FIG. 4, the data latch 208a includes T-gate 411, PMOS transistor T7, and NMOS transistor T10. Similarly, the scan latch 208b includes the T-gate 413, PMOS transistor T11, and NMOS transistor T14. The transistors T8, T9, T12, and T13 form a pair of cross-coupled inverters that are shared by both the data latch 208a and scan latch 208b. Likewise, inverter 417 is shared by both the data latch 208a and scan latch 208b.

In one embodiment, the T-gate 411 is coupled to receive clock signals D̅C̅l̅k̅ and DClk. As above, when DClk is low and D̅C̅l̅k̅ is high, the T-gate 411 is passing the data on the datapath. Similarly, during scan mode T-gate 413 passes scan data during operation of the scan clock signals SClk and S̅C̅l̅k̅.

During normal operation (i.e., not scan mode) in a given clock cycle, when DClk is low and D̅C̅l̅k̅ is high, the T-gate 411 passes the data signal to the node between transistors T8 and T9, to inverter 417 and on to the input of slave latch unit 209. Because DClk is low and D̅C̅l̅k̅ is high, transistors T7 and T10 are not conducting, and since SE is inactive in one embodiment SClk is held high and S̅C̅l̅k̅ is held low. Accordingly, if the data has a logic value of one, transistor T13 conducts bringing the node between transistors T12 and T13 to a logic value of zero. This zero value appears at the gates of transistors T8 and T9, thereby causing transistor T8 to conduct. Upon the rising edge of DClk and the falling edge of D̅C̅l̅k̅, T-gate 411 stops conducting and transistors T7 and T10 begin conducting. Since transistor T8 is conducting, a path from VDD to the node between transistors T8 and T9 is created, thereby reinforcing and latching the logic value of one at the node. Thus the data value is now captured in the data latch 208a. Had the data been a logic value of zero, transistor T9 would have been conducting instead of T8, thereby reinforcing and latching a logic value of zero at the node. As mentioned above, the captured value is now available at the slave latch unit 209, which captures the data value upon a rising edge of C̅l̅k̅.

In one embodiment, during scan mode the SE signal becomes active (e.g., a logic value of one). Accordingly, as described above, the DClk and D̅C̅l̅k̅ signals may be held inactive (e.g., logic values of one and zero respectively), causing transistors T7 and T10 to begin conducting. In addition, the SClk and S̅C̅l̅k̅ signals become active causing the T-gate 413 to begin conducting when SClk is low and S̅C̅l̅k̅ is high. This allows the SDI signal to pass through the T-gate 413 to the node between transistors T12 and T13, and to the gates of transistors T8 and T9. If the SDI value is a logic value of one, transistor T9 turns on. Since transistors T7 and T10 are conducting, a logic value of zero appears at the node between transistors T8 and T9 (which overwrites the previous captured data value), at inverter 417, and also at the gates of transistors T12 and T13. It is noted that in contrast to the data value, the scan data value is inverted. However in one embodiment, the SDO path in the slave latch unit 209 may include additional inverter stages (not shown), to correct for the inverted scan data signal.

Upon the rising edge of SClk and the falling edge of S̅C̅l̅k̅, T-gate 413 stops conducting and transistors T11 and T14 begin conducting. Since transistor T12 is conducting, a path from VDD to the node between transistors T3 and T4 is created, thereby reinforcing and latching the logic value of one at the node between transistors T12 and T13. Thus the scan data value is now captured in the scan data latch 208b. Had the data been a logic value of zero, transistors T8 and T13 would have been conducting, thereby reinforcing and latching a logic value of zero at the node between T12 and T13, and a logic value of one would be placed on the node between transistors T8 and T9. As mentioned above, the captured value is now available at the slave latch unit 209, which captures the scan data value upon a rising edge of C̅l̅k̅.

Similar to the embodiment of FIG. 3, during scan mode several clock cycles worth of scan data may be scanned through the scan chain. Accordingly, the SE signal may stay active long enough to clock all the scan data through the scan chain.

Accordingly, from the above descriptions of the embodiments, the scan datapath is separated from and in parallel with the normal datapath through the master latch unit 207. In one embodiment, this separation may allow the logic that was previously used as the scan input mux to be used as logic that may be in the datapath anyway, as described above. Accordingly, one or more logic stages may be saved and the accompanying datapath delay may be improved. In addition, the clock select circuit 211 of FIG. 2 may add a delay to the master data latch clock and the master scan latch clock, which may improve skew tolerance by allowing data that arrives late to still be latched.

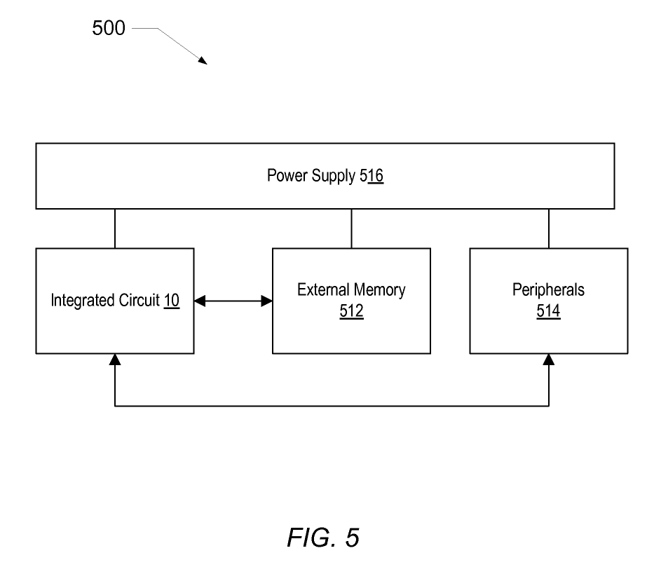

It is noted that the embodiments shown and described above may be implemented on an integrated circuit. It is further noted that in one embodiment, integrated circuit 10 may be a processor chip, a communication chip, a controller, or the like. One such embodiment is shown in FIG. 5.

Turning to FIG. 5, a block diagram of one embodiment of a system 500 including the integrated circuit 10 is shown. The system 500 includes at least one instance of the integrated circuit 10 of FIG. 1 coupled to one or more peripherals 514 and an external memory 512. The system 500 also includes a power supply 516 that may provide one or more supply voltages to the integrated circuit 10 as well as one or more supply voltages to the memory 512 and/or the peripherals 514. In some embodiments, more than one instance of the integrated circuit 10 may be included.

The external memory 512 may be any desired memory. For example, the memory may include dynamic random access memory (DRAM), static RAM (SRAM), flash memory, or combinations thereof. The DRAM may include synchronous DRAM (SDRAM), double data rate (DDR) SDRAM, DDR2 SDRAM, DDR3 SDRAM, etc.

The peripherals 514 may include any desired circuitry, depending on the type of system 500. For example, in one embodiment, the system 500 may be a mobile device and the peripherals 514 may include devices for various types of wireless communication, such as WiFi, Bluetooth, cellular, global position system, etc. The peripherals 514 may also include additional storage, including RAM storage, solid-state storage, or disk storage. The peripherals 514 may include user interface devices such as a display screen, including touch display screens or multi-touch display screens, keyboard or other keys, microphones, speakers, etc.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. A flip-flop circuit comprising:
a master latch unit including a first data input coupled to receive a data signal;
a slave latch unit including a second data input coupled to an output line of the master latch unit;
wherein the master latch unit includes a data latch and a scan latch, wherein the scan latch is coupled in parallel with the data latch to the output line of the master latch unit; and
a clock select circuit configured to selectively provide a clock signal to one of the data latch or the scan latch dependent upon a scan enable signal.

2. The flip-flop circuit as recited in claim 1, wherein in response to receiving the clock signal, the data latch is configured to latch and output a data value received on the first data input.

3. The flip-flop circuit as recited in claim 1, wherein in response to receiving the clock signal, the scan latch is configured to latch and output a scan data value received on a scan data input.

4. The flip-flop circuit as recited in claim 2, further comprising an embedded logic circuit including combinatorial logic configured to perform a predetermined logic function, wherein the embedded logic circuit is configured to receive one or more data signals and to provide the data value to the first data input of the master latch unit.

5. The flip-flop circuit as recited in claim 1, wherein the clock select circuit is further configured to delay a system clock signal by a predetermined amount to generate the clock signal.

6. The flip-flop circuit as recited in claim 5, wherein the predetermined amount corresponds to a clock slew value between the system clock at its source and the system clock at clock select circuit.

7. An integrated circuit comprising:
a first circuit; and
flip-flop circuit coupled to receive and latch a data value from the first circuit,
wherein the flip-flop circuit comprises:
a master latch unit including a first data input coupled to receive a data signal;
a slave latch unit including a second data input coupled to an output line of the master latch unit;
wherein the master latch unit includes a data latch and a scan latch,
wherein the scan latch is coupled in parallel with the data latch to the output line of the master latch unit; and
a clock select circuit configured to selectively provide a clock signal to one of the data latch or the scan latch dependent upon a scan enable signal.

8. The integrated circuit as recited in claim 7, wherein in response to receiving the clock signal, the data latch is configured to latch and output a data value received on the first data input, and in response to receiving the clock signal, the scan latch is configured to latch and output a scan data value received on a scan data input.

9. The integrated circuit as recited in claim 8, wherein the clock select circuit is further configured to delay a system clock signal by a predetermined amount to generate the clock signal, wherein the data latch is configured to latch a late arriving data value.

10. The integrated circuit as recited in claim 7, wherein in response to receiving the clock signal, the scan latch is configured to latch a scan data value received on a scan data input and to output the latched scan data value on the output line.

11. A flip-flop circuit comprising:
a master latch unit including a data latch configured to receive a data value on a data input, and a scan latch configured to receive a scan data value on a scan data input, wherein the data latch is configured to latch and output the data value on an output line in response to a transition of a first clock signal, and wherein the scan latch is configured to latch and output the scan data value on the output line in response to a transition of a second clock signal;
a slave latch unit coupled to the output line and configured to latch and output either the data value or the scan data value in response to a transition of a third clock signal;
a clock select circuit configured to selectively provide either the first clock signal or the second clock signal dependent upon a scan enable signal.

12. The flip-flop circuit as recited in claim 11, wherein the clock select circuit is further configured to delay a system clock signal by a predetermined amount to generate the first clock signal and the second clock signal.

13. The flip-flop circuit as recited in claim 12, wherein the predetermined amount corresponds to a clock slew value between the system clock at its source and the system clock at clock select circuit.

14. The flip-flop circuit as recited in claim 11, wherein the clock select circuit is further configured to provide the first clock signal in response to the scan enable signal being in an inactive state, and to provide the second clock in response to the scan enable signal being in an active state.

15. The flip-flop circuit as recited in claim 11, further comprising an embedded logic circuit including combinatorial logic configured to perform a predetermined logic function, wherein the embedded logic circuit is configured to receive one or more data signals and to provide the data value to the data input of the data latch.

16. The flip-flop circuit as recited in claim 11, wherein the master latch unit comprises a plurality of transistors coupled together serially in a stack between a power supply voltage and a ground reference, wherein a first portion of the plurality of transistors includes p-type metal oxide semiconductor (PMOS) transistors coupled serially together and to the to the power supply voltage, and a second portion of the plurality of transistors includes n-type metal oxide semiconductor (NMOS) transistors coupled serially together between the first portion of the PMOS transistors and the ground reference.

17. The flip-flop circuit as recited in claim 16, wherein the master latch unit further comprises a first transmission gate and a second transmission gate coupled to a node between the PMOS transistors and the NMOS transistors.

18. The flip-flop circuit as recited in claim 17, wherein the data latch includes the first transmission gate, one of the PMOS transistors, and one of the NMOS transistors, and shares an innermost PMOS transistor and innermost NMOS transistor with the scan latch.

19. The flip-flop circuit as recited in claim 17, wherein the scan latch includes the second transmission gate, one of the PMOS transistors, and one of the NMOS transistors and shares an innermost PMOS transistor and innermost NMOS transistor with the data latch.

20. The flip-flop circuit as recited in claim 17, wherein the first transmission gate is configured to convey the data value in response to the first clock signal being active, and the second transmission gate is configured to convey the scan data value in response to the second clock signal being active.
